(19) United States
(12) Patent Application Publication
(10) Pub. No.: US 2026/0113876 A1
(43) Pub. Date: Apr. 23, 2026

(54) COOLING DISTRIBUTION UNIT PIPING AND FLOW CONTROL

(71) Applicant: LTI Holdings Inc., Pleasanton, CA (US)

(72) Inventors: Steven J. Medeiros, Loudon, NH (US); Jeffrey A. Henning, Exeter, NH (US); Tristan G. Whiting, Watertown, MA (US); Peter E. Hildebrand, Haverhill, NH (US)

(21) Appl. No.: 19/359,946

(22) Filed: Oct. 16, 2025

Related U.S. Application Data
(60) Provisional application No. 63/708,592, filed on Oct. 17, 2024.

(51) Int. Cl. H05K 7/20

(52) U.S. Cl. CPC H05K 7/20272; H05K 7/20281; H05K 7/20772

(57) ABSTRACT

A cooling distribution unit includes a housing, a primary closed loop configured to circulate a first fluid to a cooling structure for removal of heat from the first fluid, and a set of piping disposed within the housing. The set of piping is a modular pipe system configured to provide a desired piping configuration for circulation of the first fluid throughout the housing. The cooling distribution unit further includes a secondary closed loop configured to circulate a second fluid to at least one electrical component and pick up heat from the at least one electrical component.

### CROSS-REFERENCE TO RELATED APPLICATIONS

This application claims priority to U.S. Provisional Application No. 63/708,592, filed Oct. 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU's) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a housing, a primary closed loop configured to circulate a first fluid to a cooling structure for removal of heat from the first fluid, and a set of piping disposed within the housing. The set of piping is a modular pipe system configured to provide a desired piping configuration for circulation of the first fluid throughout the housing. The cooling distribution unit further includes a secondary closed loop configured to circulate a second fluid to at least one electrical component and pick up heat from the at least one electrical component.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is another perspective view of the cooling distribution unit of FIG. 1.

FIG. 6 is an enlarged view of the cooling distribution unit of FIG. 1.

FIG. 7 is another enlarged view of the cooling distribution unit of FIG. 1.

### DETAILED DESCRIPTION

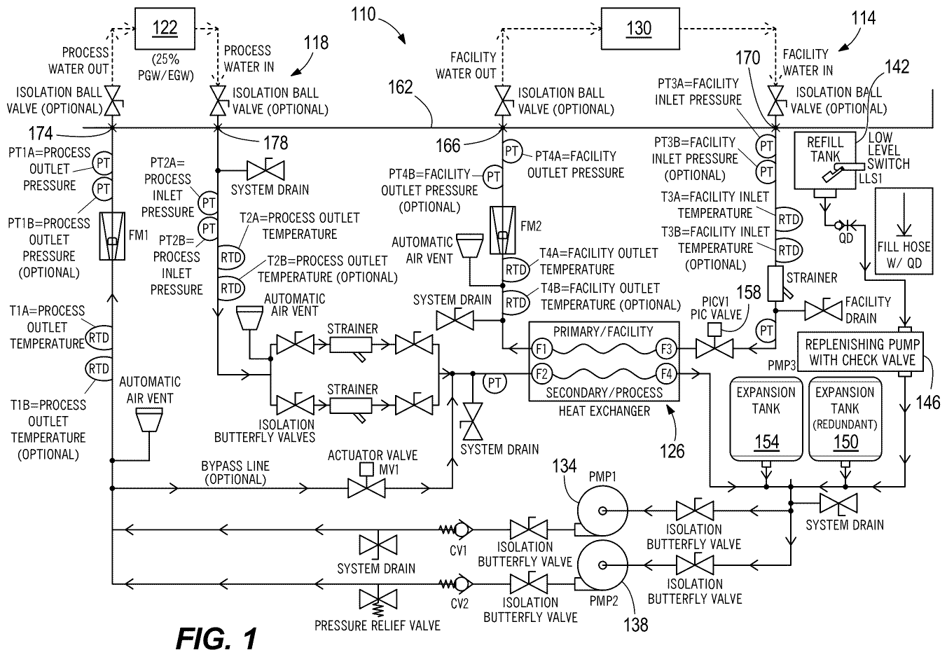

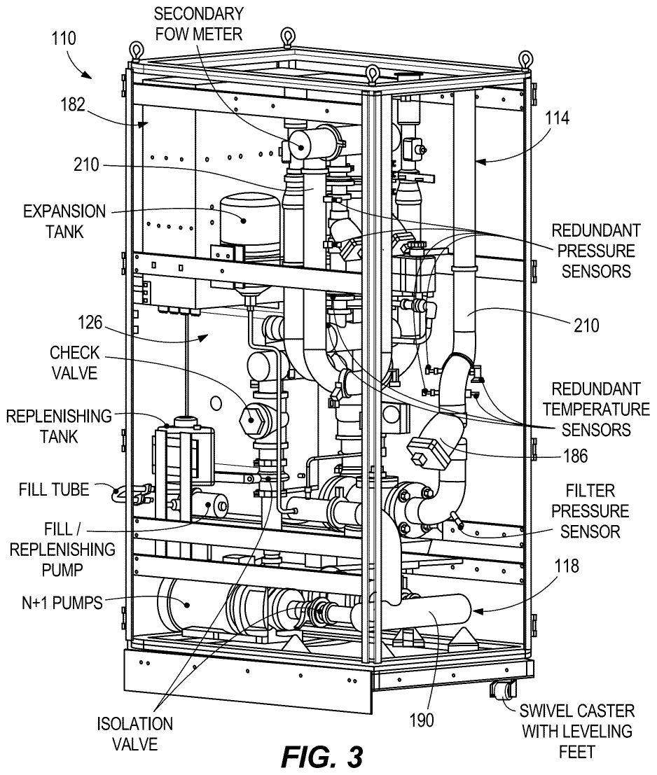

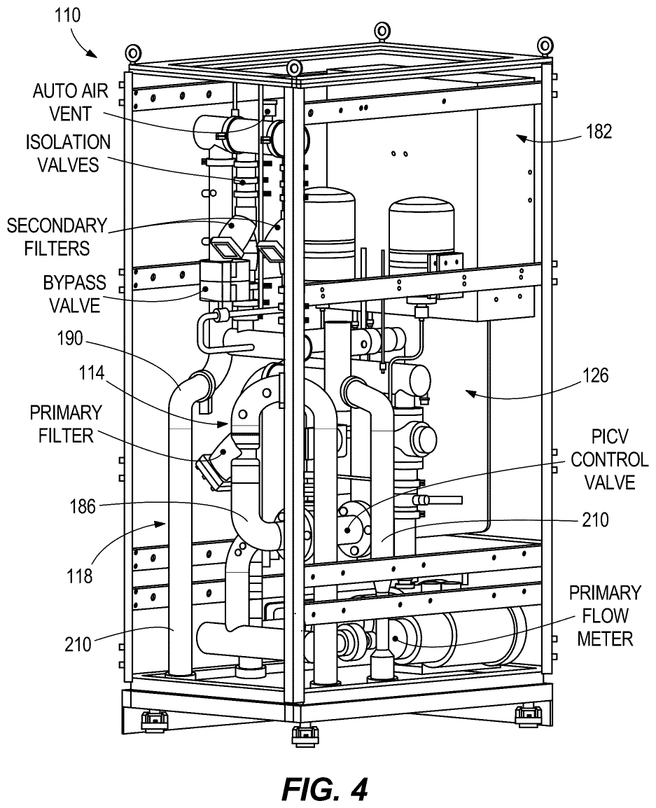

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

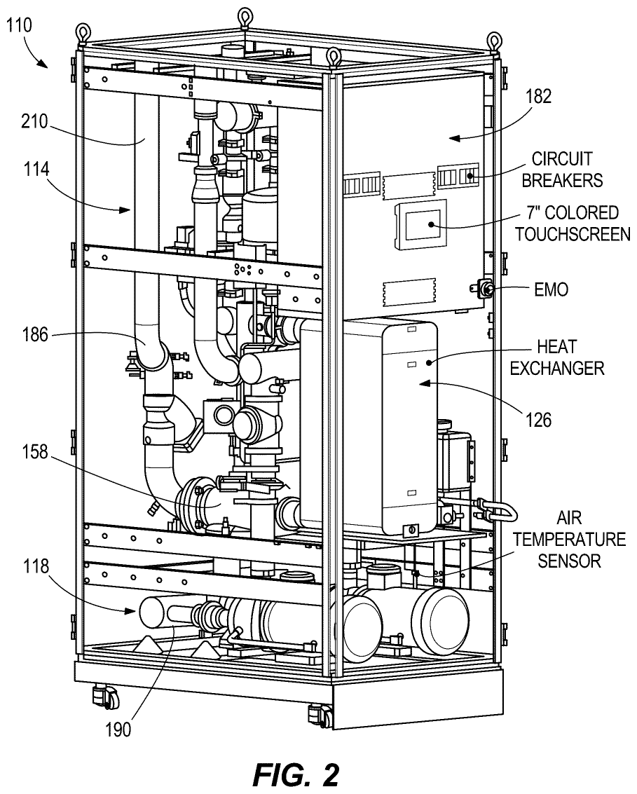

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. Other examples include other types of piping, including piping made of other materials, or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50 GPM, 100 GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control (PIC) valve 158 disposed before the heat exchanger 126 along the primary closed loop 114.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. In some examples, the housing 162 may include one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, wherein the primary closed loop 114 enters, and wherein the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

In some examples, these sensors are coupled (e.g., wired or wirelessly) to a controller 182 (FIGS. 2-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

In the illustrated example, the cooling distribution unit 110 has an overall dimension of 31.5″ by 47.4″ by 84.5″, and an overall weight of approximately 1400 pounds. Other examples may include different sizes and weights, including sizes smaller and larger than that illustrated, and weights smaller or greater than that illustrated. Additionally, in the illustrated example, the cooling distribution unit 110 may provide a cooling capacity of 550 kW (at 4° C. approach temperature difference) and 1100 kW (at 8° C. approach temperature difference). Other examples may include other values and ranges of values of cooling capacity, including a cooling capacity smaller or greater than that illustrated.

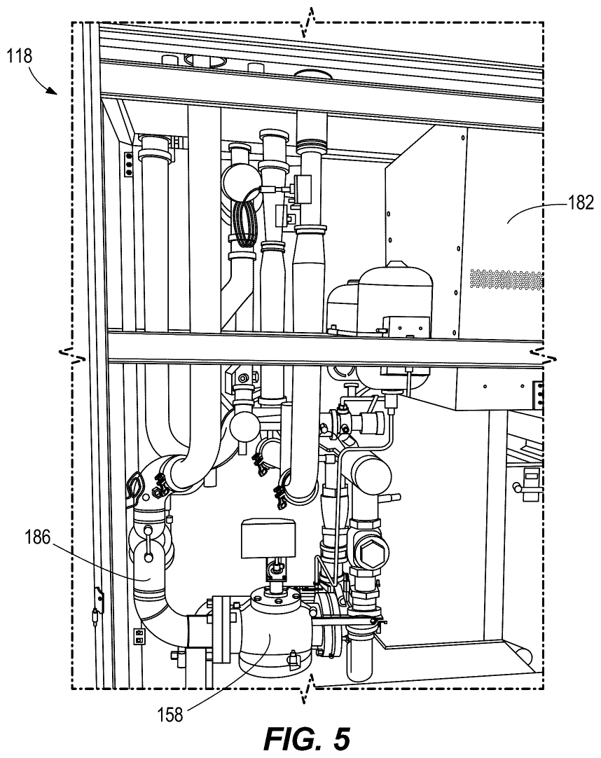

With reference to FIGS. 2-5, the piping of the primary closed loop 114 forms a first set of piping 186 and the piping of the secondary closed loop 118 forms a second set of piping 190. The first set of piping 186 and the second set of piping 190 are disposed within the housing 162. The first outlet 166 is connected to the first set of piping 186 such that the first fluid is permitted to exit the cooling distribution unit 110 to be circulated to the cooling structure 130. The first inlet 170 is connected to the first set of piping 186 such that the first fluid is permitted to enter and circulate through cooling distribution unit 110. The second outlet 174 is connected to the second set of piping 190 such that the second fluid exits the cooling distribution unit 110 to be circulated to the electrical components 122. The second inlet 178 is connected to the second set of piping 190 such that the second fluid is permitted to enter and circulate through the cooling distribution unit 110 for heat transfer between the first fluid and the second fluid.

The first set of piping 186 and the second set of piping 190 are formed as modular pipe systems configured to provide a desired piping configuration based on a user's operation requirements. The modularity of the first set of piping 186 and the second set of piping 190 allows the user to change various piping components when necessary and in a quick manner. As such, the first set of piping 186 and the second set of piping 190 are not integrally formed by a brazing process or welding process to respectively produce a solid pipe system. The first set of piping 186 and the second set of piping 190 are made of multiple piping components that are connected together by various pipe connecting mechanisms.

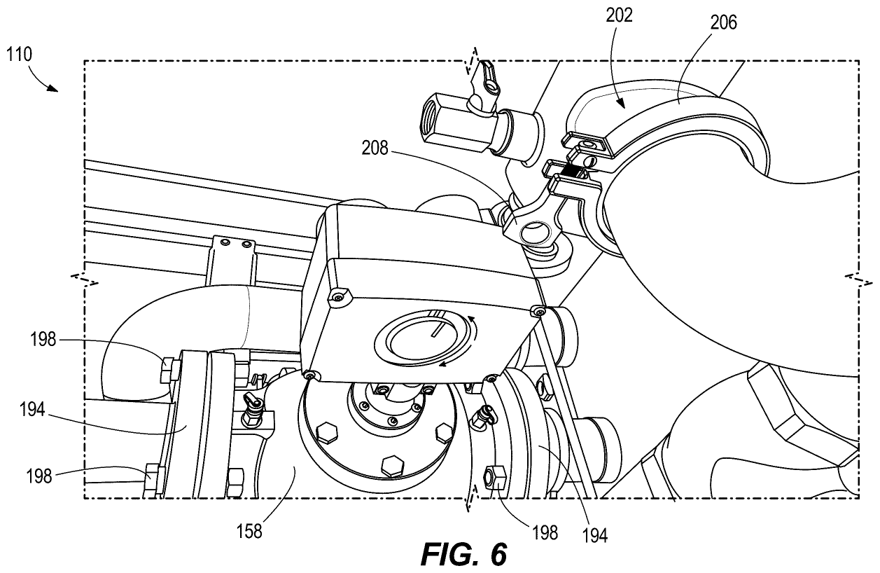

For example, as shown in FIG. 6, the PIC valve 158 is removably coupled to the first set of piping 186 by pipe flanges 194 (e.g., separate pipe flanges), through which fasteners 198 (e.g., bolts) extend for coupling the PIC valve 158 to the first set of piping 186. The user may disassemble the pipe flanges 194 and the fasteners 198 to remove the PIC valve 158 from the first set of piping 186 and interchange the PIC valve 158 with a different valve based on the user's operation requirements. The PIC valve 158 may be interchanged with a modulating control valve or other types of valves that are suitable for the user's operation requirements.

In a setting where multiple cooling distribution units 110 are provided, a respective PIC valve 158 is removably coupled to a primary closed loop 114 of a corresponding cooling distribution unit 110. Each PIC valve 158 is configured to control the flow of the first fluid through the corresponding primary closed loop 114. Also, each PIC valve 158 is controlled by a powered actuator for adjusting the PIC valves 158 between an open position and a closed position to thereby control the flow of the first fluid. The PIC valves 158 each provide a linear flow control as the pressure and the temperature of the first fluid fluctuates. The temperature of the primary closed loop 114 is efficiently controlled through the operation of each PIC valve 158 despite changes in the pressure and the temperature of the first fluid. Even though the PIC valves 158 provide efficient temperature control, a respective PIC valve 158 may be expensive and have a large amount of weight. With modularity of the first set of piping 186, the user has the option to use another valve different than the PIC valve 158 and designed to correlate with various operating requirements of the user.

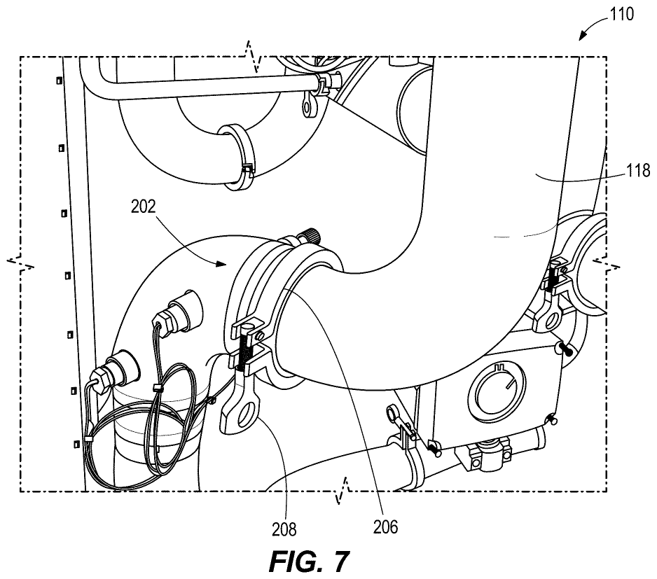

In some examples, the PIC valve 158 may be removably coupled to the first set of piping 186 by a sanitary tri-clamp 202 as shown in FIGS. 6 and 7. The sanitary tri-clamp 202 includes two flanges (not shown), a gasket (not shown), and a clamp 206. The flanges are positioned on respective pipes such that the ends of the flanges are mated together with the gasket disposed therebetween. The clamp 206 is then placed around the ends of the flanges. A tightening screw 208 is arranged to extend through the clamp 206 and is rotatable for tightening the clamp 206 to securely couple connecting pipes together. As such, the sanitary tri-clamp 202 provides an easy disassembling process, in which the user can quickly remove the sanitary tri-clamp 202 by hand or a tool (e.g., wrench). In other examples, the PIC valve 158 may be removably coupled to the first set of piping 186 by other types of pipe-connecting mechanisms.

With reference back to FIGS. 2-4, the first set of piping 186 and the second set of piping 190 also include multiple pipes that each have a straight (e.g., linear) configuration. A respective straight pipe 210 is removably coupled to other piping sections within the first set of piping 186 or the second set of piping 190 by a sanitary tri-clamp 202 for an easy assembling process and disassembling process. The straight pipes 210 are each interchangeable with another pipe (not shown) having a port that permits coupling of additional sensors. The straight pipes 210 may also be interchangeable with other pipes having different shapes and sizes that are suitable for the user's operation requirements.

All pipe connecting mechanisms for the second set of piping 190 may, for example, be sanitary couplings or hygiene connections. The sanitary couplings may be the sanitary tri-clamps 202 shown in FIGS. 6 and 7. As such, the sanitary tri-clamps 202 are easy to clean and disassemble from the second set of piping 190, thereby producing an easier maintenance process for the cooling distribution unit 110. The sanitary tri-clamps 202 also provide a quick and easy disassembling process for interchanging pipes within the second set of piping 190.

Although various aspects and examples have been described in detail with reference to certain examples illustrated in the drawings, variations and modifications exist within the scope and spirit of one or more independent aspects described and illustrated.

What is claimed is:

1. A cooling distribution unit comprising:
a housing;
a primary closed loop configured to circulate a first fluid to a cooling structure for removal of heat from the first fluid;
a set of piping disposed within the housing and being a modular pipe system configured to provide a desired piping configuration for circulation of the first fluid throughout the housing; and
a secondary closed loop configured to circulate a second fluid to an electrical component and pick up heat from the electrical component.

2. The cooling distribution unit of claim 1, wherein the primary closed loop includes a first valve removably coupled to the set of piping.

3. The cooling distribution unit of claim 2, wherein the first valve is interchangeable with a second valve, and wherein the first valve is a pressure independent control valve configured to control flow of the first fluid through the primary closed loop.

4. The cooling distribution unit of claim 2, wherein the first valve is removably coupled to the set of piping by a sanitary tri-clamp.

5. The cooling distribution unit of claim 2, wherein the first valve is removably coupled to the set of piping by a pipe flange.

6. The cooling distribution unit of claim 1, wherein the set of piping includes a first pipe removably coupled to other piping sections of the set of piping to be interchangeable with a second pipe different than the first pipe.

7. The cooling distribution unit of claim 6, wherein the first pipe has a straight configuration.

8. The cooling distribution unit of claim 6, wherein the first pipe is removably coupled to the other piping sections by a sanitary tri-clamp.

9. The cooling distribution unit of claim 1, wherein the set of piping is a first set of piping, and further comprising a second set of piping disposed within the housing and being a modular pipe system configured to provide another desired piping configuration for circulation of the second fluid throughout the housing.

10. The cooling distribution unit of claim 9, wherein the second set of piping includes pipe connecting mechanisms that are sanitary couplings.

11. The cooling distribution unit of claim 1, further comprising a heat exchanger disposed within the housing such that both the primary closed loop and the secondary closed loop extends therethrough for heat transfer between the first fluid and the second fluid.

12. The cooling distribution unit of claim 11, wherein the primary closed loop and the secondary closed loop each include a pump to respectively pump the first fluid through the primary closed loop and the second fluid through the secondary closed loop.

13. The cooling distribution unit of claim 1, wherein the set of piping includes two piping components connected together by a pipe connecting mechanism.

14. The cooling distribution unit of claim 13, wherein the pipe connecting mechanism is a clamp.

15. The cooling distribution unit of claim 14, wherein the clamp forms part of a sanitary tri-clamp.

16. The cooling distribution unit of claim 15, further comprising a tightening screw for tightening the clamp to securely couple the two piping components together.

17. The cooling distribution unit of claim 1, further comprising a pressure independent control valve.

18. The cooling distribution unit of claim 17, wherein the pressure independent control valve is removably coupled to the set of piping.

19. The cooling distribution unit of claim 18, wherein pressure independent control valve is removably coupled to two separate pipe flanges via fasteners.

20. The cooling distribution unit of claim 19, wherein the set of piping is a first set of piping, and further comprising a second set of piping disposed within the housing and being a modular pipe system configured to provide another desired piping configuration for circulation of the second fluid throughout the housing.
